(19) United States
(12) Patent Application Publication
(10) Pub. No.: US 2023/0040844 A1
(43) Pub. Date: Feb. 9, 2023

(54) RF SWITCH DEVICE AND METHOD OF MANUFACTURING SAME

(71) Applicant: DB HiTek Co., Ltd., Bucheon-si (KR)

(72) Inventors: Ki Hun LEE, Yangpyeong-gun (KR); Jin Hyo JUNG, Suwon-si (KR); Kyong Rok KIM, Bucheon-si (KR); Hyun Jin KIM, Seoul (KR); Sang Gil KIM, Cheongju-si (KR); Seung Ki KO, Yongin-si (KR); Tae Ryoong PARK, Seoul (KR)

(21) Appl. No.: 17/817,075

(22) Filed: Aug. 3, 2022

(30) Foreign Application Priority Data
Aug. 6, 2021 (KR) 10-2021-0103561

(51) Int. Cl. H01L 27/12; H01L 29/08; H01L 29/06

(52) U.S. Cl. CPC H01L 27/1203; H01L 29/0847; H01L 29/0653

(57) ABSTRACT

Provided is an RF switch device and a method of manufacturing the same and, more particularly, to an RF switch device and a method of manufacturing the same seeking to improve RF characteristics by forming a trap layer on a part of the surface of a substrate, thereby trapping carriers that may accumulate on the surface of the substrate.

### CROSS REFERENCE TO RELATED APPLICATION

The present application claims priority to Korean Patent Application No. 10-2021-0103561, filed Aug. 6, 2021, the entire contents of which is incorporated herein for all purposes by this reference.

### BACKGROUND OF THE INVENTION

### Field of the Invention

The present disclosure relates to an RF switch device and a method of manufacturing the same and, more particularly, to an RF switch device and a method of manufacturing the same seeking to improve RF characteristics by forming a trap layer on a part of the surface of a substrate, thereby trapping carriers that may accumulate on the surface of the substrate.

### Description of the Related Art

In general, a radio frequency front-end module (RF FEM) used in wireless communication devices such as a mobile phone, a smartphone, a notebook computer, a tablet PC, a PDA, a mobile game device, a multimedia device, etc. may include an RF active device, an RF passive device, an RF switch device, and a control device.

FIG. 1 is a reference diagram of a substrate for a conventional RF switch device, and FIG. 2 is a graph comparing second harmonic distortion (HD2) characteristics of a general silicon-on-insulator (SOI) wafer, an SOI wafer using a high resistivity substrate, and an SOI wafer including a trap layer is formed on a high resistivity substrate.

Hereinafter, the problems of an RF switch device on a conventional high resistivity SOI substrate 9 will be described in detail with reference to the accompanying drawings.

The conventional high resistivity SOI substrate 9 will be described with reference to FIG. 1. A buried oxide (BOX) layer 930 is formed on a high resistivity substrate (HRS) 910, and a silicon film (“Top Si”) 950 is on the BOX layer 930. The silicon film 950 is physically separated from the high resistivity substrate 910 by the BOX layer 930. However, radio frequency coupling occurs due to the parasitic capacitance formed between the high resistivity substrate 910 and the silicon film 950, and carriers may accumulate on the surface of the high resistivity substrate 910 facing the BOX layer 930. Accordingly, the surface resistance of the high resistivity substrate 910 decreases, which is referred to as parasitic surface conduction (PSC). Due to PSC, crosstalk between adjacent metal wires (e.g., on or over the silicon film 950) may occur. In addition, the resistance of the high resistivity substrate 910 may vary depending on the frequency of the input signal; that is, linearity of the resistance of the substrate 910 as a function of the RF signal frequency may deteriorate.

In order to solve these problems, a trap layer 970 between the BOX layer 930 and the high resistivity substrate 910 may trap carriers on the surface side of the high resistivity substrate 910, to reduce or eliminate PSC. As such, it is possible to obtain improved RF characteristics compared to the conventional SOI substrate 9.

Referring to FIG. 2, curve A shows the second harmonic distortion (HD2) characteristic of a typical SOI wafer with a substrate resistance of 10 ohm·com, curve B shows the HD2 characteristic of an SOI wafer having a high resistivity substrate with a substrate resistance of 1,000 ohm·com, and curve C shows the HD2 characteristics of the SOI wafer including the trap layer 970 on a high resistivity substrate. Based on input power of 15 dBm, it can be seen that the HD2 characteristic is improved by about 30 dB compared to the general SOI wafer when the high resistivity substrate 910 is present, and an additional 40 dB improvement is obtained when the trap layer 970 is present.

However, forming the trap layer 970 typically entails a complicated process, and the economical efficiency of manufacturing RF devices on such a substrate decreases due to the high cost.

### Document of Related Art

Korean Patent Application Publication No. 10-2019-0127389, “SEMICONDUCTOR DEVICE AND METHOD OF MANUFACTURING SAME.”

### SUMMARY OF THE INVENTION

The present disclosure has been made to solve the problems of the related art, and objectives of the present disclosure include providing an RF switch device and a method of manufacturing the same seeking to reduce parasitic surface conduction (PSC) by forming a trap layer on a surface of a high resistivity substrate to trap carriers that may accumulate on the surface of the substrate.

In addition, objectives of the present disclosure include providing an RF switch device and a method of manufacturing the same that simplify the manufacturing process by directly forming a trap layer in and/or on the high resistivity substrate without forming a buried oxide (BOX) layer as in the related art, thereby improving economical efficiency of the manufacturing process.

Furthermore, objectives of the present disclosure include providing an RF switch device and a method of manufacturing the same that reduce or eliminate complications in the process for forming the trap layer since a separate process for etching the substrate is not required when forming the trap layer.

According to an embodiment of the present disclosure, there is provided an RF switch device, including a high resistivity substrate; a plurality of gates on the substrate in a first region; a source and a drain in the first region; a well in the substrate; a device isolation layer in the substrate at a boundary between the first region and a second region; and a trap layer on the substrate in the second region.

According to another embodiment of the present disclosure, in the RF switch device, the trap layer may comprise poly-silicon or amorphous silicon.

According to still another embodiment of the present disclosure, the RF switch device may further include a pre-metal dielectric (PMD) layer on the trap layer and the substrate; and a plurality of metal wires spaced apart from each other on the PMD layer.

According to still another embodiment of the present disclosure, in the RF switch device, at least one of the metal wires is in the second region, and the trap layer may at least partially overlap the metal wire in the second region vertically.

According to still another embodiment of the present disclosure, in the RF switch device, the trap layer may be below the metal wire in the second region and may have a width greater than that of the metal wire in the second region.

According to still another embodiment of the present disclosure, there is provided an RF switch device, including a high resistivity substrate with a resistivity of substantially greater than 1,000 ohm·cm; a gate on the substrate in a first region; a source and a drain in a well in the first region; a device isolation layer in the substrate at a boundary between the first region and a second region; a trap layer comprising poly-silicon or amorphous silicon on the substrate in the second region; a pre-metal dielectric (PMD) layer on the trap layer and the substrate; and a plurality of metal wires spaced apart from each other on the PMD layer, wherein the trap layer may vertically overlap with one of the metal wires in the second region.

According to still another embodiment of the present disclosure, in the RF switch device, a plurality of the metal wires are in the second region, and the trap layer between adjacent ones of the plurality of metal wires in the second region may have a grid shape or a plurality of regularly-spaced openings therein.

According to still another embodiment of the present disclosure, in the RF switch device, the trap layer may between adjacent metal wires in the second region may have a stripe shape, a line shape, or an elongated rectangular shape.

According to still another embodiment of the present disclosure, in the RF switch device, the trap layer between adjacent ones of the metal wires in the second region may have a square, substantially square, or island shape, or comprises a regularly-spaced array of trap layers having such a shape.

According to still another embodiment of the present disclosure, in the RF switch device, the trap layer may completely cover an upper surface of the PMD layer in the second region.

According to still another embodiment of the present disclosure, there is provided an RF switch device, including a high resistivity substrate; a plurality of stacks, wherein each of the plurality of stacks has a gate on the substrate and a source and a drain in a well in a first region of the substrate; a device isolation layer in the substrate at a boundary between the first region and a second region; a trap layer comprising poly-silicon or amorphous silicon on the substrate in the second region; a pre-metal dielectric (PMD) layer on the trap layer and the substrate; and a plurality of metal wires spaced apart from each other on the PMD layer, wherein the trap layer may vertically overlap with one of the metal wires in the second region.

According to still another embodiment of the present disclosure, in the RF switch device, the trap layer may be in a space between individual stacks.

According to still another embodiment of the present disclosure, in the RF switch device, the trap layer may have substantially the same width as or a greater width than that of the one metal wire in the second region.

According to an embodiment of the present disclosure, there is provided a method of manufacturing an RF switch device, including forming, in a first region, a well in a high resistivity substrate; forming a device isolation layer at a boundary between the first region and a second region; forming an oxide film on a surface of the substrate; and forming a trap layer in the second region, wherein the trap layer may comprise poly-silicon or amorphous silicon.

According to another embodiment of the present disclosure, in the method of manufacturing an RF switch device, forming the trap layer may include etching the oxide film in the second region; forming a preliminary layer on the substrate and the oxide film; and etching the preliminary layer in the first region.

According to still another embodiment of the present disclosure, the method of manufacturing an RF switch device, may further include forming a gate oxide film and a gate on the surface of the substrate in the first region.

According to still another embodiment of the present disclosure, in the method of manufacturing an RF switch device, forming the gate oxide film and the gate may include forming an oxide film or layer on the trap layer and the substrate; forming a polysilicon film on the oxide film or layer; and sequentially etching the polysilicon film and the oxide film or layer.

According to still another embodiment of the present disclosure, in the method of manufacturing the RF switch device, the trap layer may have a thickness greater than that of the gate.

The present disclosure has the following effects by the above configurations.

The present disclosure can reduce parasitic surface conduction (PSC) by forming a trap layer on a surface side of a high resistivity substrate to trap carriers that accumulate on the surface of the substrate.

In addition, the present disclosure can simplify the manufacturing process by directly forming the trap layer on the high resistivity substrate without forming a buried oxide (BOX) layer as in the related art, thereby improving economical efficiency.

Furthermore, the present disclosure can reduce or prevent complications in the process for forming the trap layer since a separate etching process for the substrate is not necessary when forming the trap layer.

Meanwhile, it should be added that even if some effects are not explicitly mentioned herein, the effects expected from the technical features of the present disclosure and their potential further effects are treated as if they were described herein.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a reference diagram of a conventional substrate for an RF switch device;

FIG. 2 is a graph comparing HD2 characteristics of a general SOI wafer, an SOI wafer including a high resistivity substrate, and an SOI wafer including a trap layer on a high resistivity substrate;

FIG. 3 is a cross-sectional view of an RF switch device according to a first embodiment of the present disclosure;

FIGS. 4 to 6 are cross-sectional views for explaining the relative widths of the trap layer and a metal wire in the region A21;

FIG. 7 is a plan view showing a trap layer according to the first embodiment having a rectangular or plate shape in the region A22;

FIG. 8 is a plan view showing a trap layer according to a second embodiment having a grid shape or a plurality of regularly-spaced openings in the region A22;

FIG. 9 is a plan view showing a trap layer according to a third embodiment having an elongated rectangular or line shape;

FIG. 10 is a plan view showing a trap layer according to a fourth embodiment having a square, substantially square or island shape, or comprising a regularly-spaced array of trap layers having such a shape;

FIG. 11 is a plan view showing a peripheral trap layer around a stack in a stacked RF switch device;

FIG. 12 is a plan view showing a trap layer between adjacent stacks or transistors and in the periphery of a stack or a plurality of such transistors in a stacked RF switch device; and

FIGS. 13 to 20 are cross-sectional views for reference for explaining a method of manufacturing an RF switch device according to an embodiment of the present disclosure.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those skilled in the art.

As used herein, the singular form may include the plural form unless the context clearly dictates otherwise. Furthermore, as used herein, the terms “comprise” and “comprising” refers to the specific existence of the recited shapes, numbers, steps, actions, members, elements, groups thereof, etc., and does not exclude the presence or addition of one or more other shapes, numbers, actions, members, elements, groups, etc.

Hereinafter, it should be noted that when one component (or layer) is described as being on another component (or layer), one component may be directly on the other component, or one or more third components or layers may be between the one component and the other component. In addition, when one component is expressed as being directly on or above another component, no other components are between the one component and the other component. Moreover, being located on “top,” “above,” “below,” “bottom” or a “side” of a component means a relative positional relationship.

The terms “first,” “second,” “third,” etc. may be used to describe various items such as various components, regions and/or parts. However, the items are not limited by these terms.

In addition, it should be noted that, where certain embodiments are otherwise feasible, certain process sequences may be performed other than as described below. For example, two processes described in succession may be performed substantially simultaneously or in the reverse order.

Furthermore, the conductivity or dopant type in a doped region or component may be defined as “p-type” or “n-type” according to the main carrier characteristics, but this is only for convenience of description, and the technical spirit of the present disclosure is not limited to what is illustrated. For example, hereinafter, “p-type” and “n-type” may be replaced with the more general terms “first conductivity type” and “second conductivity type.” Herein, the first conductivity type may refer to p-type, and the second conductivity type may refer to n-type.

Furthermore, it should be understood that the terms “high concentration” and “low concentration” (or “heavily” and “lightly”) in reference to the doping concentration of the impurity region refer to the doping concentration of one component relative to one or more other components.

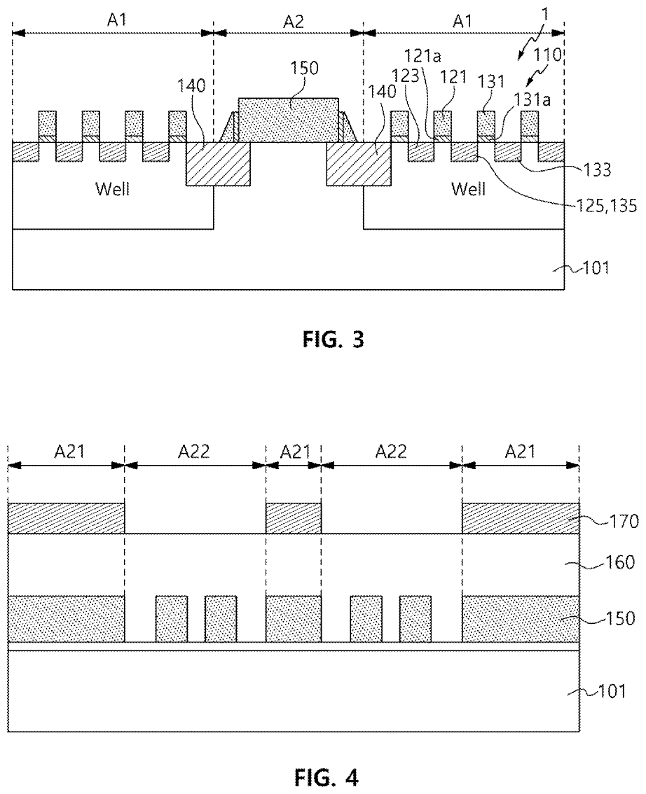

FIG. 3 is a cross-sectional view of an RF switch device according to an embodiment of the present disclosure.

Hereinafter, an RF switch device 1 according to an embodiment of the present disclosure will be described in detail with reference to the accompanying drawings.

Referring to FIG. 3, the present disclosure relates to an RF switch device 1 and, more particularly, to an RF switch device 1 seeking to improve RF characteristics by forming a trap layer on a part of the surface of a substrate 101, thereby trapping carriers that may accumulate on the surface of the substrate 101.

The RF switch device is on and/or in a high resistivity substrate 101. The substrate 101 may comprise a silicon substrate. To be specific, the substrate 101 may be lightly doped with a first conductivity type impurity such as B or In or a second conductivity type impurity such as P or As. In addition, it is preferable that the substrate 101 has a resistivity of about 1,000 ohm·cm or more, and more preferable that the substrate 101 has a resistivity of 1,000 ohm·cm or more and 20,000 ohm·cm or less, but is not limited thereto.

The switch device 1 includes a first region A1 including active elements and a well, and a second, peripheral region A2. One or more field effect transistors 110 may be in the first region A1. For example, a plurality of field effect transistors 110 may be spaced apart from each other in the first region A1. Each transistor 110 may include a source and a drain in the substrate 101, and a gate on the surface of the substrate 101. In general, sources and drains in field effect transistors may be referred to as “source/drain terminals.”

For example, a plurality of gates are on the surface of the substrate 101. A source 123 and a drain 125 having the second conductivity type may be on opposite sides of a first gate 121 in the substrate 101 and/or at the surface of the substrate 101. A well having the first conductivity type may be in the substrate 101 and may surround the source 123 and the drain 125.

In addition, a source 133 and a drain 135 having the first conductivity type may be in the substrate 101 and/or at the surface of the substrate 101, on opposite sides of a second gate 131. A well having a second conductivity type may be in the substrate 101 and may surround the source 133 and the drain 135.

As such, complementary metal-oxide semiconductor (CMOS) devices may be in the first region A1, but there is no particular limitation thereto, and the scope of the present disclosure is not limited by the above examples. A first gate oxide film 121a may be under the first gate 121, and a second gate oxide film 131a may be under the second gate 131.

In addition, a device isolation layer 140 defining the active region (e.g., containing the field effect transistors 110) may be at the boundary between the first region A1 and the second region A2. The device isolation layer 140 may be formed by shallow trench isolation (STI), and may comprise, for example, a silicon oxide (e.g., undoped silicon dioxide). The device isolation layer 140 may be at the boundary between the first region A1 and the second region A2, and may be in both the first region A1 and the second region A2, for example, or may be completely within the first region A1, but is not limited thereto.

In the second region A2, a trap layer 150 is on the surface of the substrate 101. The trap layer 150 may be formed, for example, by blanket deposition of poly-silicon or amorphous silicon on the substrate 101 and then etching (e.g., using a patterned photoresist as a mask), or by epitaxy (e.g., epitaxial growth of silicon from an exposed surface of the substrate 101 in the second region A2, in the presence of a blocking mask over the surface of the substrate 101 in the first region A1 and any devices such as field effect transistors 110 thereon), but is not limited thereto. The trap layer 150 is on the substrate 101 in the second region A2, and thus, during the formation, an etching process on the surface of the substrate 101 is not performed, accordingly, the process for forming the trap layer 150 may be simplified.

The trap layer 150 may be on the substrate 101 in the second region A2, and if necessary, on the device isolation layer 140. Optionally, the trap layer 150 may have a sidewall spacer (not identified) on one or more sidewalls thereof. The sidewall spacer may be formed conventionally (e.g., by conformal deposition of a thin layer of silicon dioxide, conformal deposition of a thicker layer of polysilicon thereon, and anisotropically etching the polysilicon and silicon dioxide layers to expose the uppermost surface of the trap layer 150).

Hereinafter, the structure of the RF switch device 9 on a conventional high resistivity substrate and problems thereof will be described in detail once again.

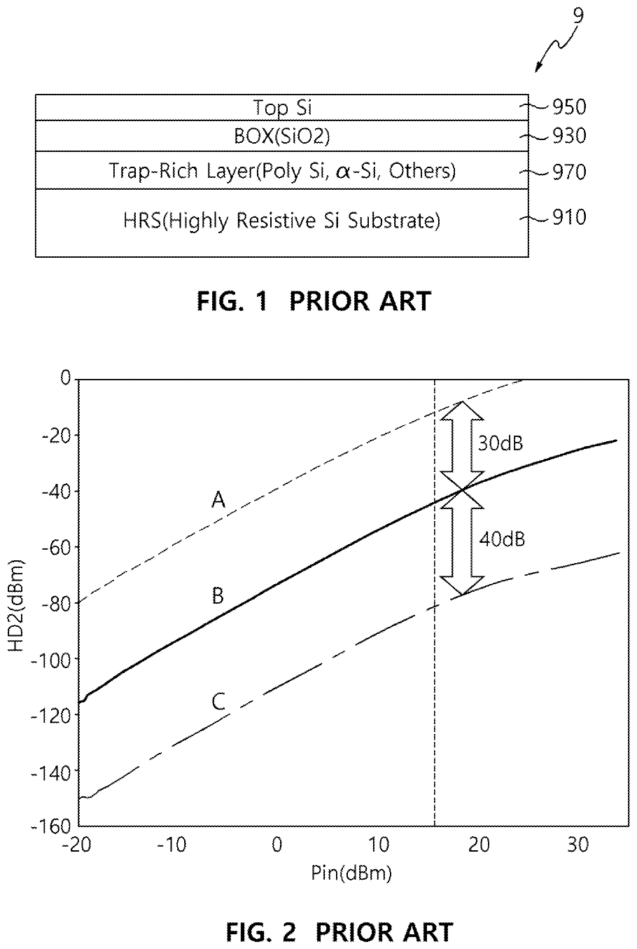

The conventional device 9 will be described with reference to FIG. 1. A buried oxide (BOX) layer 930 is on a high resistivity substrate (HRS) 910, and a silicon film (Top Si) 950 is on the BOX layer 930. The silicon film 950 is physically separated from the high resistivity substrate 910 by the BOX layer 930, however, radio frequency coupling occurs due to the parasitic capacitance formed between the high resistivity substrate 910 and the silicon film 950, and carriers accumulate on the surface of the high resistivity substrate 910 facing the BOX layer 930. Accordingly, the surface resistance of the high resistivity substrate 910 decreases, which is referred to as parasitic surface conduction (PSC). Due to PSC, crosstalk between adjacent metal wires (e.g., on or over the silicon film 950) may occur. In addition, the resistance of the high resistivity substrate 910 may vary depending on the frequency of the input signal, that is, linearity of the resistance of the substrate 910 as a function of the RF signal frequency may deteriorate.

In order to solve these problems, a trap layer 970 between the BOX layer 930 and the high resistivity substrate 910 may trap carriers on the surface side of the high resistivity substrate 910, to reduce or eliminate PSC. As such, it is possible to obtain improved RF characteristics compared to the conventional SOI substrate 9.

Referring to FIG. 2, curve A shows the second harmonic distortion (HD2) characteristic of a typical SOI wafer with a substrate resistance of 10 ohm·com, curve B shows the HD2 characteristic of an SOI wafer having a high resistivity substrate with a substrate resistance of 1,000 ohm·com, and curve C shows the HD2 characteristics of the SOI wafer including the trap layer 970 on a high resistivity substrate. Based on input power of 15 dBm, it can be seen that the HD2 characteristic is improved by about 30 dB compared to the general SOI wafer when the high resistivity substrate 910 is present, and an additional 40 dB improvement is obtained when the trap layer 970 is present.

However, forming the trap layer 970 typically entails a complicated process, and the economical efficiency of manufacturing RF devices on such a substrate decreases due to the high cost.

Referring to FIG. 3, in order to avoid such problems, the RF switch device 1 according to a first embodiment of the present disclosure is characterized in that the trap layer 150 is on the surface of the high resistivity substrate 101 in the second region A2 outside of the first region A1. Unlike the conventional structure, the RF switch device 1 is characterized in that the trap layer 150 is directly on the high resistivity substrate 101, and does not include a separate BOX layer. This may promote the simplification of the manufacturing process.

In addition, referring to FIG. 4, a pre-metal dielectric (PMD) layer 160 is on the substrate 101 and on the trap layer 150, and one or more metal wires 170 are on the PMD layer 160. Hereinafter, in the second region A2, a region vertically overlapping a metal wire 170 is referred to as a region A21, and other region(s) (i.e., not vertically overlapping a metal wire 170) are referred to as region(s) A22. In other words, each region A22 is a space between adjacent metal wires 170 in the second region A2.

FIGS. 4 to 6 are cross-sectional views for explaining the relative widths of the trap layer 150 and the metal wire(s) 170 in the region A21.

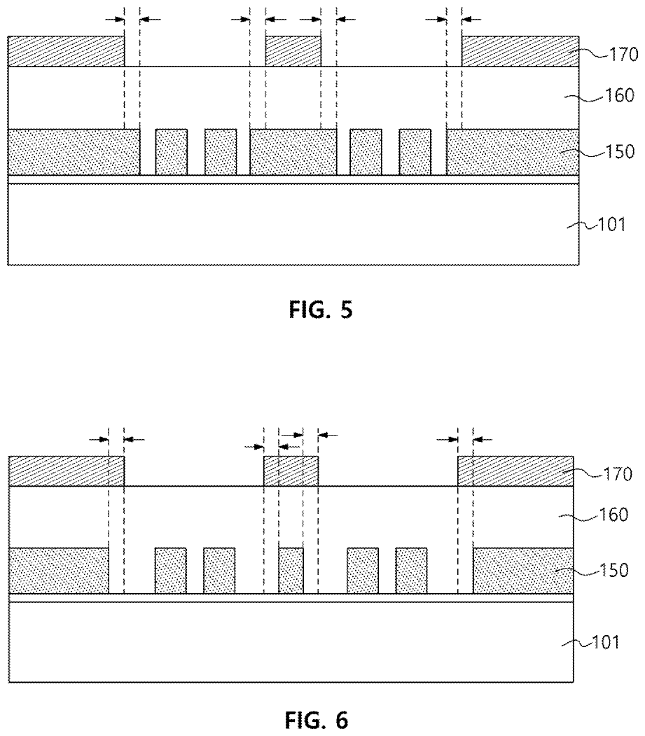

Preferably, in the second region A2 (FIG. 3), the trap layer 150 is at least partially overlaps the individual metal wire 170 in the vertical direction. In the second region A2, the trap layer 150 may have substantially the same length or width as the overlying metal wire 170 (see FIG. 4), a larger length or width than the overlying metal wire 170 (see FIG. 5), or a smaller length or width than the overlying metal wire 170 (see FIG. 6), but there is no limitation thereto. As an example, referring to FIG. 5, it is desirable that the trap layer 150 under the individual metal wire 170 completely overlaps the overlying metal wire 170 in the vertical direction, but has a slightly larger width than the metal wire 170 in order to reduce parasitic surface conduction (PSC). Hereinafter, the left-right direction shown in the drawings will be described as the “x-axis direction,” the direction orthogonal to the horizontal plane of the substrate 101 in FIGS. 4-6 will be described as the “y-axis direction,” and the direction orthogonal to both the x-axis direction and the y-axis direction will be described as the “z-axis direction.”

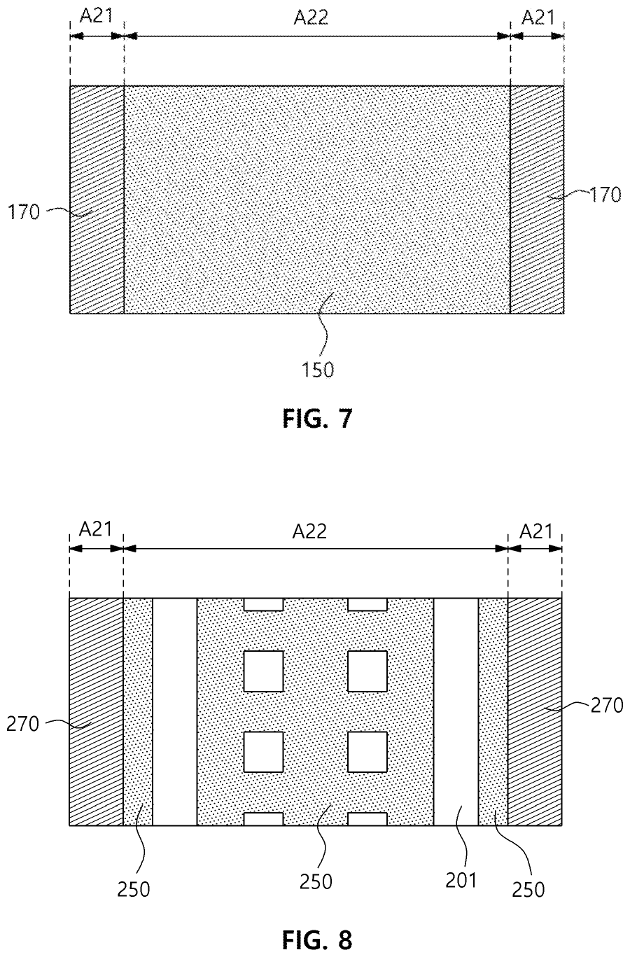

FIG. 7 is a plan view showing a trap layer according to a first embodiment having a rectangular or plate shape in the region A22.

Referring to FIG. 7, the trap layer 150 may be in the region A22. In the first embodiment, the trap layer 150 may cover all of the region A22. For example, the trap layer 150 may have a rectangular or plate shape, or comprise a single line or layer covering the entire second region A2.

FIG. 8 is a plan view showing a trap layer according to a second embodiment having a grid shape, or a plurality of regularly-spaced openings in the region A22.

Referring to FIG. 8, in the second embodiment, the trap layer 250 may have one or more sidewalls in contact with the PMD layer 160 in the x-axis direction and/or the z-axis direction in the region A22. That is, the trap layer 150 and one or more portions of the PMD layer 160 may be horizontally adjacent to each other and/or may alternate in the x-axis and/or z-axis direction. For example, the trap layer 250 may have a grid shape and/or an array of regularly-spaced openings in the region A22, and the pattern density of the openings in the trap layer 250 may be adjusted.

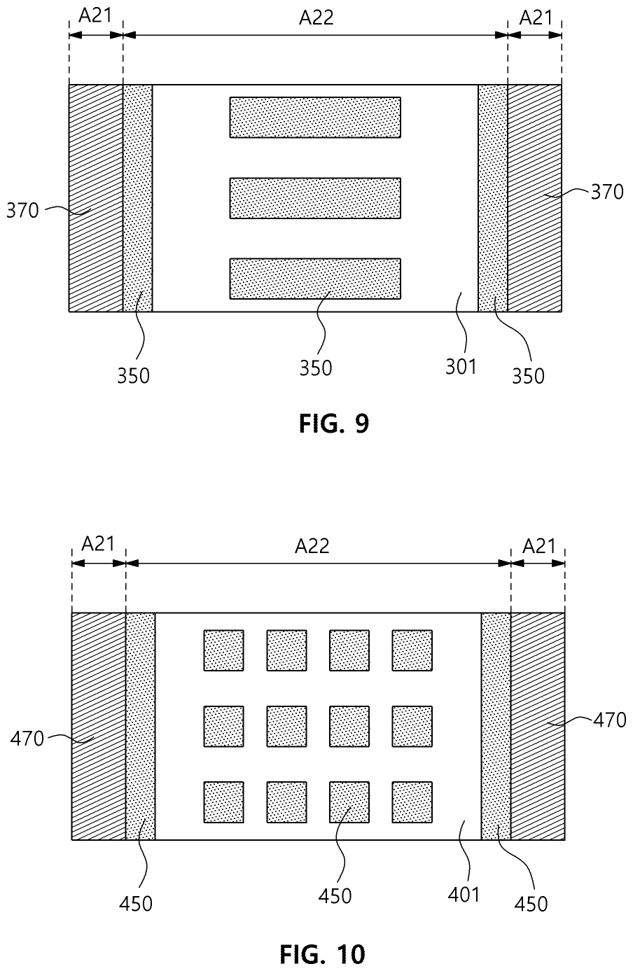

FIG. 9 is a plan view showing a trap layer according to a third embodiment having a line or elongated rectangular shape or comprising one or more lines.

Referring to FIG. 9, in the third embodiment, a plurality of trap layers 350 may have an elongated rectangular or line shape with a length along the x-axis direction, in which the trap layers 350 are spaced apart from each other in the z-axis direction in the region A22 and extend a predetermined length along the x-axis direction. Individual ones of the trap layers 350 in the region A22 may be connected to a corresponding (portion of the) trap layer 350 in the region A21. Conversely, the plurality of trap layers 350 may be aligned in the z-axis direction. That is, the trap layer 350 may have a stripe shape in the A22 region.

FIG. 10 is a plan view showing a trap layer according to a fourth embodiment having an island or substantially square shape.

Referring to FIG. 10, in the fourth embodiment, each of a plurality of trap layers 450 may have a square or substantially square shape or a form of an island in the region A22, or comprise a regularly-spaced array of layers 450 having such a shape. In the above-described examples, the trap layers 150, 250, 350, and 450 at least partially overlap the metal wires 170, 270, 370, 470 in the region A21, and preferably, the trap layers 150, 250, 350, and 450 may overlap the front surfaces of the metal wires 170, 270, 370, and 470 (e.g., in the region A21). The structures in the above embodiments effectively remove or reduce PSC under the metal wires 170, 270, 370, and 470 and reduce between crosstalk between adjacent ones of the metal wires 170, 270, 370, and 470.

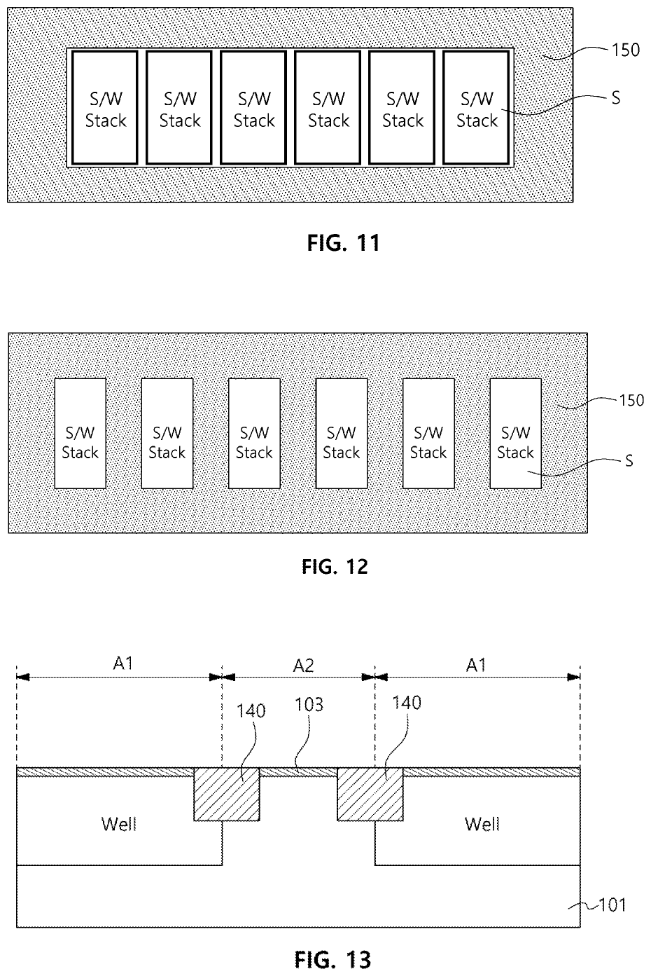

FIG. 11 is a plan view showing a trap layer in an area peripheral to one or more stacks in a stacked RF switch device, and FIG. 12 is a plan view showing a trap layer between adjacent stacks and in the area peripheral to the stacks in a stacked RF switch device.

Referring to FIGS. 11 and 12, in a general RF switch device in a stacked configuration, the trap layer 150 may be only around on in the area peripheral to a stack S, or it may be in the space between adjacent stacks S, but is not limited thereto. Here, a “stacked configuration” means that two or more transistors are connected in series to increase the breakdown voltage that a single transistor can withstand in isolation mode under high voltage operating conditions. In other words, individual stacks or transistors are connected in series to form a stacked configuration. A single CMOS device may be in each stage or “stack.”

FIGS. 13 to 20 are cross-sectional views for reference for explaining a method of manufacturing an RF switch device according to one or more embodiments of the present disclosure.

Hereinafter, a method of manufacturing an RF switch device according to one or more embodiments of the present disclosure will be described in detail with reference to the accompanying drawings.

First, referring to FIG. 13, one or more wells Well and one or more device isolation layers 140 are formed in the high resistivity substrate 101. To be specific, the well(s) Well are formed in the substrate 101 in the first region A1, and the device isolation layer(s) 140 are formed at the boundary between the first region A1 and the second region A2. The well(s) Well may be formed, for example, by ion implantation using a photoresist pattern (not shown) as an implantation mask. As previously mentioned, the device isolation layer(s) 140 may be formed in the first region A1 near the boundary or may be in both the first region A1 and the second region A2, but is not limited thereto. An oxide film 103 is formed on the substrate 101 before, during or after formation of the device isolation layer 140. The oxide film 103 may be formed, for example, to a thickness of several tens of A (e.g., 20-50 A). The oxide film 103 is in the first region A1 and the second region A2.

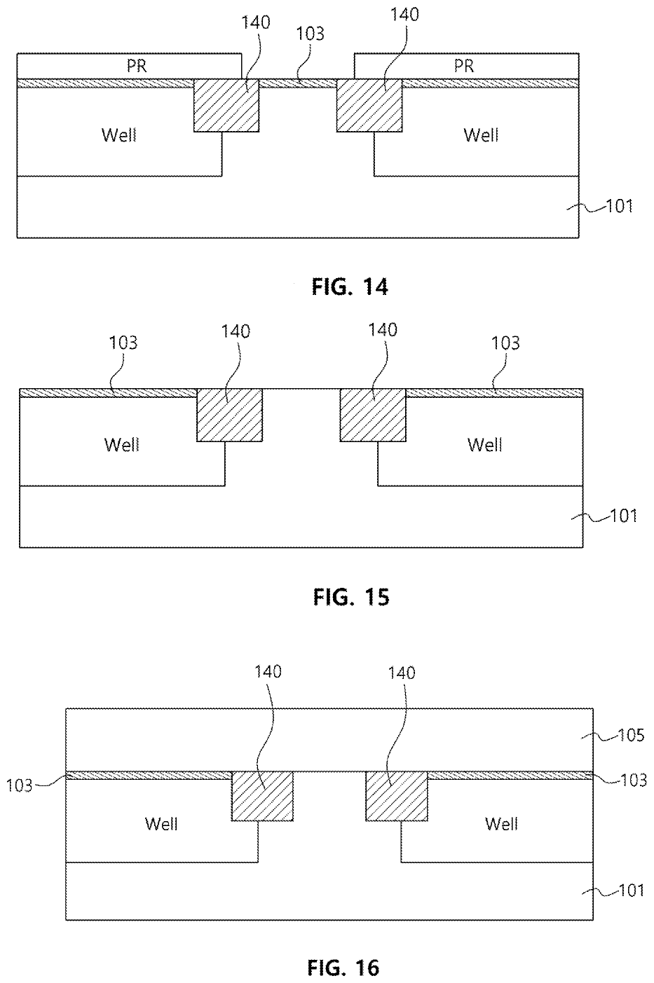

Thereafter, referring to FIGS. 14 and 15, the oxide film 103 in the second region A2 is selectively removed. To be specific, for example, a photoresist PR pattern having an opening in the second region A2 is formed on the substrate 101 (see FIG. 14), then the exposed oxide film 103 in the second region A2 side may be removed by etching (see FIG. 15). When the oxide film 103 remains on the surface of the substrate in the second region A2, PSC may deteriorate RF characteristics (e.g., due to accumulation of carriers on the surface of the substrate 101 in the second region A2 and resulting crosstalk in metal wires above the substrate 101 in the second region A2), so the oxide film 103 generally must be removed. In this case, etching may comprise, for example, wet etching.

Then, referring to FIG. 16, a preliminary layer 105 comprising a poly-silicon or amorphous silicon layer for forming the trap layer 150 is deposited on the surface of the substrate 101 in both the first region A1 and the second region A2. The preliminary layer 105 may be blanket-deposited on the substrate 101 or epitaxially grown (which may not form the preliminary layer 105 in the first region A1), but is not limited thereto.

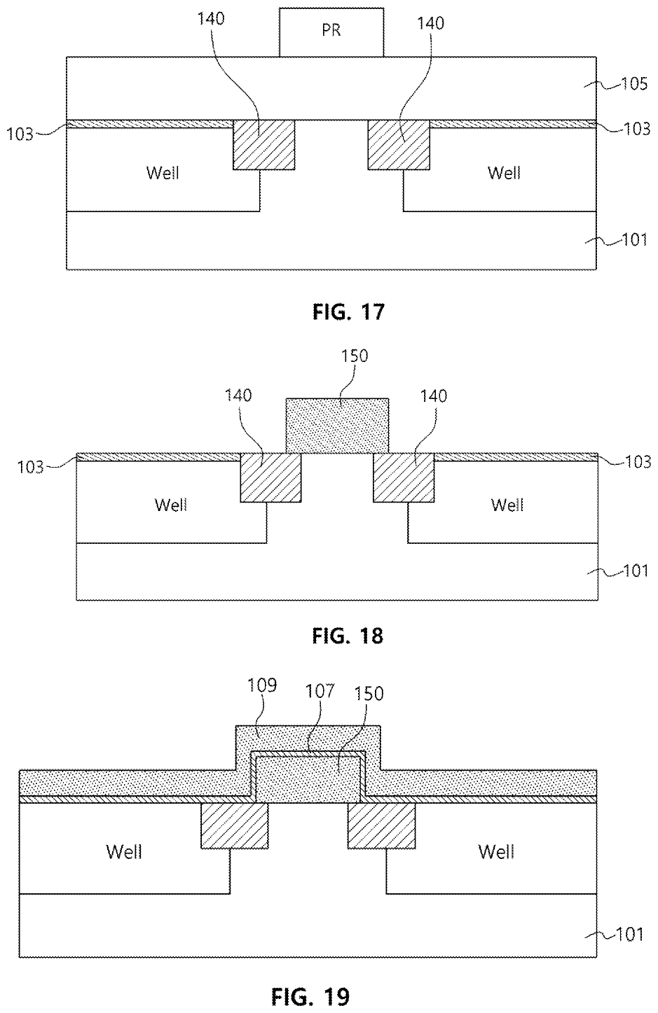

Thereafter, referring to FIG. 17, a photoresist PR pattern is formed on the preliminary layer 105 in the second region A2, corresponding to locations of the trap layer 150 (e.g., by conventional photoresist deposition and patterning). Then, referring to FIG. 18, the preliminary layer 105 exposed in the first region A1 (and, in certain embodiments, in parts of the second region A2) is etched. Accordingly, the trap layer 150 is formed in the second region A2. As described above, the trap layer 150 may have a rectangular shape, an elongated rectangular shape, a square or substantially square shape, a plurality of regularly-spaced openings in an array, a plate shape, a grid shape, a stripe shape, an island shape in the second region A2, but is not limited thereto.

Thereafter, referring to FIG. 19, an oxide film or layer 107 (which may form gate oxide films 121a and 131a) is deposited on the surface of the substrate 101 in the first region A1 and on the trap layer 150 in the second region A2. Alternatively, the oxide film or layer 107 may be thermally grown (e.g., by thermal oxidation of silicon). The oxide film or layer 107 may be deposited on the surface of the substrate 101 in the first region A1 (or grown in exposed areas of the substrate 101 in the first region A1) and deposited or grown on the sidewalls and top surface of the trap layer 150 in the second region A2. Furthermore, a polysilicon film 109 is deposited on the oxide film layer 107. The polysilicon film 109 may have a thickness less than that of the trap layer 150.

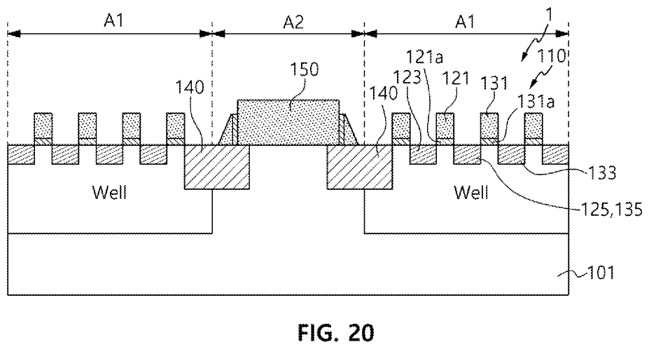

Thereafter, referring to FIG. 20, after a photoresist pattern (not shown) is formed on the polysilicon film 109, the polysilicon film 109 and the oxide film layer 107 are sequentially etched to form the gates 121, 131, . . . and the gate oxide films 121a, 131a, . . . in the first region A1.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiment describes the best state for implementing the technical idea of the present disclosure, and various changes useful in a specific application and/or field and other uses of the present disclosure are possible. Accordingly, the detailed description of the present disclosure is not intended to limit the present disclosure to the disclosed embodiments.

What is claimed is:

1. An RF switch device, comprising:
a high resistivity substrate;
a plurality of gates on the substrate in a first region;
a source and a drain in the first region;
a well in the substrate;
a device isolation layer in the substrate at a boundary between the first region and a second region; and
a trap layer on the substrate in the second region.

2. The RF switch device of claim 1, wherein the trap layer comprises poly-silicon or amorphous silicon.

3. The RF switch device of claim 2, further comprising:
a pre-metal dielectric (PMD) layer on the trap layer and the substrate; and
a plurality of metal wires spaced apart from each other on the PMD layer.

4. The RF switch device of claim 3, wherein at least one of the metal wires is in the second region, and the trap layer at least partially overlaps the at least one metal wire in the second region vertically.

5. The RF switch device of claim 3, wherein the trap layer is below the at least one metal wire in the second region and has a width greater than that of the at least one metal wire in the second region.

6. An RF switch device, comprising:
a high resistivity substrate with a resistivity of substantially greater than 1,000 ohm·cm;
a gate on the substrate in a first region;
a source and a drain in a well in the first region;
a device isolation layer in the substrate at a boundary between the first region and a second region;
a trap layer comprising poly-silicon or amorphous silicon on the substrate in the second region;
a pre-metal dielectric (PMD) layer on the trap layer and the substrate; and
a plurality of metal wires spaced apart from each other on the PMD layer,
wherein the trap layer vertically overlaps one of the metal wires in the second region.

7. The RF switch device of claim 6, wherein a plurality of the metal wires are in the second region.

8. The RF switch device of claim 7, wherein the trap layer between adjacent ones of the metal wires in the second region has a grid shape or a plurality of regularly-spaced openings therein.

9. The RF switch device of claim 7, wherein the trap layer between adjacent ones of the metal wires in the second region has a stripe shape, a line shape, or an elongated rectangular shape.

10. The RF switch device of claim 7, wherein the trap layer between adjacent ones of the metal wires in the second region has a square, substantially square, or island shape.

11. The RF switch device of claim 6, wherein the trap layer completely covers an upper surface of the PMD layer in the second region.

12. An RF switch device, comprising:
a high resistivity substrate;
a plurality of stacks, wherein each of the plurality of stacks has a gate on the substrate and a source and a drain in a well in a first region of the substrate;
a device isolation layer in the substrate at a boundary between the first region and a second region;
a trap layer comprising poly-silicon or amorphous silicon on the substrate in the second region;
a pre-metal dielectric (PMD) layer on the trap layer and the substrate; and
a plurality of metal wires spaced apart from each other on the PMD layer,
wherein the trap layer vertically overlaps one of the metal wires in the second region.

13. The RF switch device of claim 12, wherein the trap layer is in a space between two of the stacks.

14. The RF switch device of claim 12, wherein the trap layer has substantially a same width as or a greater width than that of the one metal wire in the second region.

15. A method of manufacturing an RF switch device, the method comprising:
forming, in a first region, a well in a high resistivity substrate;
forming a device isolation layer at a boundary between the first region and a second region;
forming an oxide film on a surface of the substrate; and
forming a trap layer in the second region,
wherein the trap layer comprises poly-silicon or amorphous silicon.

16. The method of manufacturing an RF switch device of claim 15, wherein forming the trap layer comprises:
etching the oxide film in the second region;
forming a preliminary layer on the substrate and the oxide film; and
etching the preliminary layer in the first region.

17. The method of manufacturing the RF switch device of claim 15, further comprising:
forming a gate oxide film and a gate on the surface of the substrate in the first region.

18. The method of manufacturing the RF switch device of claim 17, wherein forming the gate oxide film and the gate comprises:
forming an oxide film or layer on the trap layer and the substrate;
forming a polysilicon film on the oxide film or layer; and
sequentially etching the polysilicon film and the oxide film or layer.

19. The method of manufacturing the RF switch device of claim 15, wherein the trap layer has a thickness greater than that of the gate.
